(19) United States
(12) Patent Application Publication
(10) Pub. No.: US 2020/0024483 A1
(43) Pub. Date: Jan. 23, 2020

(54) AQUEOUS DISPERSION FOR CHEMICAL MECHANICAL POLISHING AND METHOD OF PRODUCING THE SAME

(71) Applicant: JSR Corporation, Minato-ku (JP)

(72) Inventors: Masashi Okamoto, Minato-ku (JP); Yuuji Hirai, Minato-ku (JP); Eiichirou Kunitani, Minato-ku (JP); Kouji Nakanishi, Minato-ku (JP)

(73) Assignee: JSR Corporation, Minato-ku (JP)

(21) Appl. No.: 16/441,049

(22) Filed: Jun. 14, 2019

(30) Foreign Application Priority Data
Jul. 23, 2018 (JP) 2018-137452

(51) Int. Cl. C09G 1/02

(52) U.S. Cl. CPC C09G 1/02; H01L 21/30625

(57) ABSTRACT

An aqueous dispersion for chemical mechanical polishing includes: (A) silica particles; (B) at least one kind selected from the group consisting of organic acids and salts thereof; and (C) at least one kind selected from the group consisting of amino group-containing silane compounds and condensates thereof, and has a pH of 7 or more and 14 or less.

Japanese Patent Application No. 2018-137452, filed on Jul. 23, 2018, is hereby incorporated by reference in its entirety.

### BACKGROUND OF THE INVENTION

The present invention relates to an aqueous dispersion for chemical mechanical polishing and a method of producing the same.

Chemical mechanical polishing (CMP) has rapidly become widespread, for example, as a planarization technology in the production of a semiconductor device. The CMP is a technology involving pressing an object to be polished against a polishing pad, and causing the object to be polished and the polishing pad to slide with respect to each other while supplying an aqueous dispersion for chemical mechanical polishing onto the polishing pad, to thereby chemically and mechanically polish the object to be polished.

In recent years, along with miniaturization of the semiconductor device, a wiring layer including wiring, a plug, and the like formed in the semiconductor device has been increasingly fine. Along with this, a planarization method through the CMP has been used for the wiring layer. A substrate in the semiconductor device includes: an insulating film material; a wiring material; a barrier metal material for preventing diffusion of the wiring material into an inorganic material film; and the like. Herein, for example, silicon dioxide is used as a major insulating film material. For example, copper and tungsten are used as major wiring materials. For example, tantalum nitride and titanium nitride are used as major barrier metal materials.

Meanwhile, in order to suppress signal delay in association with multilayer wiring of the substrate, a low dielectric constant (low-k) insulating film is utilized as the insulating film material. The low dielectric constant insulating film has properties of being soft and fragile as compared to a conventional silicon dioxide film, and hence there is a problem in that it is difficult to polish and remove the film with a related-art aqueous dispersion for chemical mechanical polishing. As a chemical mechanical polishing composition for such low dielectric constant insulating film, there is proposed, for example, a chemical mechanical polishing composition including silica particles, a cationic compound, a carboxylic acid, an oxidizing agent, water, and the like and having a pH adjusted to from 1 to 6 (for example, see JP-T-2012-503329).

In the chemical mechanical polishing composition described in JP-T-2012-503329, the silica particles and the cationic compound are present in a solution adjusted to an acidic region, and hence the silica particles have high zeta potential values. This can probably contribute to polishing of the low dielectric constant insulating film at a high rate. However, the pH of the chemical mechanical polishing composition is liable to affect surface conditions of the wiring material, the insulating film material, the barrier metal material, and the like each serving as an object to be polished. Therefore, in CMP in consideration of a surface state of an object to be polished, in order to achieve polishing of those materials at high rates and obtain a surface to be polished in a satisfactory state in which polishing flaws are reduced, there remains room for improvement.

### SUMMARY

The invention can provide an aqueous dispersion for chemical mechanical polishing that enables polishing of a wiring material, an insulating film material, and a barrier metal material at high rates, and can reduce the occurrence of polishing flaws on a surface to be polished, and a method of producing the aqueous dispersion for chemical mechanical polishing.

According to a first aspect of the invention, there is provided an aqueous dispersion for chemical mechanical polishing, including: (A) silica particles; (B) at least one kind selected from the group consisting of organic acids and salts thereof; and (C) at least one kind selected from the group consisting of amino group-containing silane compounds and condensates thereof, and having a pH of 7 or more and 14 or less.

According to a second aspect of the invention, there is provided a method of producing an aqueous dispersion for chemical mechanical polishing, including: a first step of adding (A) silica particles, (B) at least one kind selected from the group consisting of organic acids and salts thereof, and (C) at least one kind selected from the group consisting of amino group-containing silane compounds and condensates thereof to water so that, when a content of the component (C) is represented by W_{C} (mass %) and a content of the component (A) is represented by W_{A} (mass %), a ratio W_{C}/W_{A} is 0.01 or more and 1 or less, to thereby obtain an aqueous dispersion; and a second step of further adding (D) an oxidizing agent to the aqueous dispersion after the first step.

### BRIEF DESCRIPTION OF THE SEVERAL VIEWS OF THE DRAWING

FIG. 1 is a perspective view for schematically illustrating a chemical mechanical polishing apparatus.

### DETAILED DESCRIPTION OF THE EMBODIMENT

The invention has been made in order to solve at least part of the above-mentioned problems, and can be realized as any one of the following embodiments.

According to one embodiment of the invention, there is provided an aqueous dispersion for chemical mechanical polishing, including: (A) silica particles; (B) at least one kind selected from the group consisting of organic acids and salts thereof; and (C) at least one kind selected from the group consisting of amino group-containing silane compounds and condensates thereof, and has a pH of 7 or more and 14 or less.

In the aqueous dispersion for chemical mechanical polishing, when a content of the component (C) is represented by W_{C} (mass %) and a content of the component (A) is represented by W_{A} (mass %), a ratio W_{C}/W_{A} may be 0.01 or more and 1 or less.

In the aqueous dispersion for chemical mechanical polishing, when a content of the component (C) is represented by W_{C} (mass %) and a content of the component (A) is represented by W_{A} (mass %), a ratio W_{C}/W_{A} may be 0.03 or more and 0.5 or less.

In the aqueous dispersion for chemical mechanical polishing, the component (C) may include an aminoalkoxysilane.

In the aqueous dispersion for chemical mechanical polishing, the component (C) may include an aminopropyltrialkoxysilane.

In the aqueous dispersion for chemical mechanical polishing, a content of the component (A) with respect to a total mass of the aqueous dispersion for chemical mechanical polishing may be 0.05 mass % or more and 10 mass % or less.

In the aqueous dispersion for chemical mechanical polishing, a content of the component (B) with respect to a total mass of the aqueous dispersion for chemical mechanical polishing may be 0.001 mass % or more and 2 mass % or less.

In the aqueous dispersion for chemical mechanical polishing, a content of the component (C) with respect to a total mass of the aqueous dispersion for chemical mechanical polishing may be 0.005 mass % or more and 10 mass % or less.

The aqueous dispersion for chemical mechanical polishing may further include (D) an oxidizing agent.

In the aqueous dispersion for chemical mechanical polishing, a content of the component (D) with respect to a total mass of the aqueous dispersion for chemical mechanical polishing may be 0.001 mass % or more and 5 mass % or less.

The aqueous dispersion for chemical mechanical polishing may be used for polishing of a substrate including two or more kinds selected from the group consisting of silicon nitride, silicon dioxide, amorphous silicon, tungsten, copper, cobalt, titanium, ruthenium, titanium nitride, and tantalum nitride.

According to one embodiment of the invention, there is provided a method of producing an aqueous dispersion for chemical mechanical polishing, including: a first step of adding (A) silica particles, (B) at least one kind selected from the group consisting of organic acids and salts thereof, and (C) at least one kind selected from the group consisting of amino group-containing silane compounds and condensates thereof to water so that, when a content of the component (C) is represented by W_{C} (mass %) and a content of the component (A) is represented by W_{A} (mass %), a ratio W_{C}/W_{A} is 0.01 or more and 1 or less, to thereby obtain an aqueous dispersion; and a second step of further adding (D) an oxidizing agent to the aqueous dispersion after the first step.

According to the above aqueous dispersion for chemical mechanical polishing, a wiring material, an insulating film material, and a barrier metal material can be polished at high rates. Further, according to the above aqueous dispersion for chemical mechanical polishing, the silica particles can be improved in dispersibility and dispersion stability, and hence the occurrence of polishing flaws on a surface to be polished can be reduced.

Preferred embodiments of the invention are described in detail below. The invention is not limited to the following embodiments, and includes various modifications performed without changing the gist of the invention.

The “wiring material” refers to a conductive metal material, such as aluminum, copper, cobalt, titanium, ruthenium, or tungsten. The “insulating film material” refers to a material such as silicon dioxide, silicon nitride, or amorphous silicon. The “barrier metal material” refers to a material that is used by being laminated with the wiring material for the purpose of improving the reliability of wiring, such as tantalum nitride or titanium nitride.

### 1. AQUEOUS DISPERSION FOR CHEMICAL MECHANICAL POLISHING

An aqueous dispersion for chemical mechanical polishing according to a first embodiment of the invention includes: (A) silica particles (sometimes referred to as “component (A)”); (B) at least one kind selected from the group consisting of organic acids and salts thereof (sometimes referred to as “component (B)”); and (C) at least one kind selected from the group consisting of amino group-containing silane compounds and condensates thereof (sometimes referred to as “component (C)”), and has a pH of 7 or more and 14 or less. The components contained in the aqueous dispersion for chemical mechanical polishing according to the first embodiment are described in detail below.

### 1.1. (A) Silica Particles

The aqueous dispersion for chemical mechanical polishing according to the first embodiment includes silica particles (A). The silica particles (A) have a function of mechanically polishing the wiring material, the insulating film material, and the barrier metal material, and increasing polishing rates of these materials. The silica particles (A) have satisfactory dispersibility and dispersion stability when interacting with a component (C) described below in the aqueous dispersion for chemical mechanical polishing. As a result, the occurrence of polishing flaws on the surface to be polished can be reduced.

Examples of the silica particles (A) include fumed silica and colloidal silica. Of those, colloidal silica is preferred. As the colloidal silica, for example, one produced by a method described in JP-A-2003-109921 may be used.

The average particle diameter of the silica particles (A) is not particularly limited, but a lower limit thereof is preferably 5 nm, more preferably 10 nm, particularly preferably 15 nm, and an upper limit thereof is preferably 300 nm, more preferably 150 nm, particularly preferably 100 nm. When the average particle diameter of the silica particles (A) falls within the above-mentioned range, the occurrence of polishing flaws on the surface to be polished can be reduced in some cases while the polishing rates of the wiring material, the insulating film material, and the barrier metal material are increased. When the average particle diameter of the silica particles (A) is equal to or less than 150 nm, which is the upper limit in the above-mentioned range, the polishing rates of the wiring material, the insulating film material, and the barrier metal material can be further increased in some cases. In addition, when the average particle diameter of the silica particles (A) is equal to or more than 10 nm, which is the lower limit, the occurrence of the polishing flaws on the surface to be polished can be further reduced in some cases.

The average particle diameter of the silica particles (A) may be determined by measurement with a particle size distribution analyzer that utilizes a dynamic light scattering method as a measurement principle. Examples of the particle diameter measurement apparatus based on the dynamic light scattering method include a dynamic light-scattering particle size analyzer “LB-550” manufactured by HORIBA, Ltd., a nanoparticle analyzer “Della Nano S” manufactured by Beckman Coulter, Inc., and “Zetasizer Nano ZS” manufactured by Malvern Panalytical Ltd. The average particle diameter measured using the dynamic light scattering method represents the average particle diameter of secondary particles each formed by aggregation of a plurality of primary particles.

A lower limit value of the content of the silica particles (A) with respect to the total mass of the aqueous dispersion for chemical mechanical polishing is preferably 0.05 mass %, more preferably 0.1 mass %, particularly preferably 0.3 mass %. When the content of the silica particles (A) is equal to or more than the above-mentioned lower limit value, polishing rates sufficient for polishing of the wiring material, the insulating film material, and the barrier metal material are obtained in some cases. Meanwhile, an upper limit value of the content of the silica particles (A) with respect to the total mass of the aqueous dispersion for chemical mechanical polishing is preferably 10 mass %, more preferably 5 mass %, particularly preferably 3 mass %. When the content of the silica particles (A) is equal to or less than the above-mentioned upper limit value, satisfactory storage stability can be easily obtained, and satisfactory planarity of the surface to be polished and the reduction of polishing flaws on the surface to be polished can be achieved in some cases.

### 1.2. (B) Organic Acid and Salt Thereof

The aqueous dispersion for chemical mechanical polishing according to the first embodiment includes (B) at least one kind selected from the group consisting of organic acids and salts thereof. When the aqueous dispersion for chemical mechanical polishing according to the first embodiment includes the component (B), the component (B) coordinates to the surface to be polished to increase a polishing rate, and precipitation of a metal salt during polishing can be reduced. In addition, when the component (B) coordinates to the surface to be polished, damage of the surface to be polished owing to etching and corrosion can be reduced in some cases.

Preferred examples of the component (B) include organic acids each having an ability to coordinate to an ion or an atom of an element constituting the wiring material, and salts thereof. As such component (B), an organic acid having 0 or 1 hydroxyl group and 1 or 2 carboxyl groups in one molecule is more preferred, and an organic acid having 0 or 1 hydroxyl group and 1 or 2 carboxyl groups in one molecule and having a first acidity constant pKa of from 1.5 to 4.5 is particularly preferred. Such component (B) has a high ability to coordinate to a surface of the wiring material or the like, and hence the polishing rate of the wiring material or the like can be increased. In addition, such component (B) can stabilize a metal ion generated through polishing of the wiring material or the like to reduce the precipitation of a metal salt, and hence a high level of planarity is obtained while surface roughening on the surface to be polished is reduced, and the occurrence of polishing flaws on the wiring material or the like can be reduced.

Of the components (B), specific examples of the organic acids include: lactic acid, tartaric acid, fumaric acid, glycolic acid, phthalic acid, maleic acid, formic acid, acetic acid, oxalic acid, citric acid, malic acid, malonic acid, glutaric acid, succinic acid, benzoic acid, p-hydroxybenzoic acid, quinolinic acid, quinaldinic acid, and amido sulfuric acid; and amino acids, such as glycine, alanine, aspartic acid, glutamic acid, lysine, arginine, tryptophan, an aromatic amino acid, and a heterocyclic amino acid. Of those, maleic acid, succinic acid, lactic acid, malonic acid, p-hydroxybenzoic acid, and glycolic acid are preferred, and maleic acid and malonic acid are more preferred. The components (B) may be used alone or in combination thereof at any ratio.

Of the component (B), specific examples of the salt of the organic acid may include salts of the organic acids given as examples above, and salts of the organic acids each formed through a reaction with a separately added base in the aqueous dispersion for chemical mechanical polishing. Examples of such base include: alkali metal hydroxides, such as sodium hydroxide, potassium hydroxide, rubidium hydroxide, and cesium hydroxide; organic alkali compounds, such as tetramethylammonium hydroxide (TMAH) and choline; and ammonia.

A lower limit value of the content of the component (B) with respect to the total mass of the aqueous dispersion for chemical mechanical polishing is preferably 0.001 mass %, more preferably 0.01 mass %, particularly preferably 0.1 mass %. Meanwhile, an upper limit value of the content of the component (B) with respect to the total mass of the aqueous dispersion for chemical mechanical polishing is preferably 2 mass %, more preferably 1 mass %, particularly preferably 0.5 mass %. When the content of the component (B) falls within the above-mentioned range, polishing rates sufficient for polishing of the wiring material, the insulating film material, and the harrier metal material are obtained, and the occurrence of polishing flaws on the surface to be polished may be reduced through reduction of the precipitation of a metal salt in some cases.

### 1.3. (C) Amino Group-Containing Silane Compound and Condensate Thereof

The aqueous dispersion for chemical mechanical polishing according to the first embodiment includes (C) at least one kind selected from the group consisting of amino group-containing silane compounds and condensates thereof. When the aqueous dispersion for chemical mechanical polishing according to the first embodiment includes the component (C), the silica particles (A) and the component (C) interact with each other to allow the silica particles (A) to have positive surface potentials. Moreover, in a pH region of from 7 to 14, a surface to be polished of the wiring material, the insulating film material, the barrier metal material, or the like is negatively charged, and hence the positively charged silica particles (A) are easily brought into contact with the surface to be polished, with the result that the polishing rates of these materials can be increased. Further, it is presumed that the component (C) that does not interact with the silica particles (A) forms a condensate with another component (C). It is presumed that the condensate has a high positive charge, and hence contributes to improvement in dispersibility and dispersion stability of the positively charged silica particles (A). As a result, it is considered that the occurrence of polishing flaws on the surface to be polished can be effectively reduced.

Specific examples of the component (C) include N-(2-aminoethyl)-3-aminopropylmethyldimethoxysilane, N-(2-aminoethyl)-3-aminopropylmethyldiethoxysilane, N-(2-aminoethyl)-3-aminopropylmethyldipropoxysilane, N-(2-aminoethyl)-3-aminopropylmethyldiisopropoxysilane, N-(2-aminoethyl)-3-aminopropyltrimethoxysilane, N-(2-aminoethyl)-3-aminopropyltriethoxysilane, N-(2-aminoethyl)-3-aminopropyltripropoxysilane, N-(2-aminoethyl)-3-aminopropyltriisopropoxysilane, N-(2-aminoethyl)-3-aminoisobutyldimethylmethoxysilane, N-(2-aminoethyl)-3-aminoisobutylmethyldimethoxysilane, N-(2-aminoethyl)-11-aminoundecyltrimethoxysilane, N-(2-aminoethyl)-3-aminopropylsilanetriol, 3-aminopropyltrimethoxysilane, 3-aminopropyltriethoxysilane, 3-triethoxysilyl-N-(1,3-dimethyl-butylidene)propylamine, N-phenyl-3-aminopropyltrimethoxysilane, N,N-bis[3-(trimethoxysilyl)propyl]ethylenediamine, (aminoethylaminoethyl)phenyltrimethoxysilane, (aminoethylaminoethyl)phenyltriethoxysilane, (aminoethylaminoethyl)phenyltripropoxysilane, (aminoethylaminoethyl)phenyltriisopropoxysilane, (aminoethylaminomethyl)phenyltrimethoxysilane, (aminoethylaminomethyl)phenyltriethoxysilane, (aminoethylaminomethyl)phenyltripropoxysilane, (aminoethylaminomethyl)phenyltriisopropoxysilane, N-(vinylbenzyl)-2-aminoethyl-3-aminopropyltrimethoxysilane, N-(vinylbenzyl)-2-aminoethyl-3-aminopropylmethyldimethoxysilane, N-β-(N-vinylbenzylaminoethyl)-N-γ-(N-vinylbenzyl)-γ-aminopropyltrimethoxysilane, N-β-(N-di(vinylbenzyl)aminoethyl)-γ-aminopropyltrimethoxysilane, N-β-(N-di(vinylbenzyl)aminoethyl)-N-γ-(N-vinylbenzyl)-γ-aminopropyltrimethoxysilane, methylbenzylaminoethylaminopropyltrimethoxysilane, dimethylbenzylaminoethylaminopropyltrimethoxysilane, benzylaminoethylaminopropyltrimethoxysilane, benzylaminoethylaminopropyltriethoxysilane, 3-ureidopropyltriethoxysilane, 3-(N-phenyl)aminopropyltrimethoxysilane, N,N-bis[3-(trimethoxysilyl)propyl]ethylenediamine, (aminoethylaminoethyl)phenethyltrimethoxysilane, (aminoethylaminoethyl)phenethyltriethoxysilane, (aminoethylaminoethyl)phenethyltripropoxysilane, (aminoethylaminoethyl)phenethyltriisopropoxysilane, (aminoethylaminomethyl)phenethyltrimethoxysilane, (aminoethylaminomethyl)phenethyltriethoxysilane, (aminoethylaminomethyl)phenethyltripropoxysilane, (aminoethylaminomethyl)phenethyltriisopropoxysilane, N-[2-[3-(trimethoxysilyl)propylamino]ethyl]ethylenediamine, N-[2-[3-(triethoxysilyl)propylamino]ethyl]ethylencdiamine, N-[2-[3-(tripropoxysilyl)propylamino]ethyl]ethylenediamine, and N-[2-[3-(triisopropoxysilyl)propylamino]ethyl]ethylenediamine. Of those, an aminoalkoxysilane is preferred and an aminopropyltrialkoxysilane is more preferred in order to increase the polishing rate of the wiring material or the like and reduce, in particular, the occurrence of the polishing flaws on the surface to be polished. Of the aminopropyltrialkoxysilanes, N-(2-aminoethyl)-3-aminopropyltrimethoxysilane, 3-aminopropyltrimethoxysilane, and 3-aminopropyltriethoxysilane are preferred, and 3-aminopropyltriethoxysilane is more preferred. The components (C) may be used alone or in combination thereof at any ratio.

A lower limit value of the content of the component (C) with respect to the total mass of the aqueous dispersion for chemical mechanical polishing is preferably 0.005 mass %, more preferably 0.01 mass %, particularly preferably 0.03 mass %. When the content of the component (C) is equal to or more than the above-mentioned lower limit value, the component (C) easily interacts with the silica particles (A), and the polishing rate for the surface to be polished can be further increased in some cases. Meanwhile, an upper limit value of the content of the component (C) with respect to the total mass of the aqueous dispersion for chemical mechanical polishing is preferably 10 mass %, more preferably 5 mass %, particularly preferably 1 mass %. When the content of the component (C) is equal to or less than the above-mentioned upper limit value, polishing characteristics are less liable to deteriorate in some cases.

In addition, in the aqueous dispersion for chemical mechanical polishing according to the first embodiment, when the content of the component (C) and the content of the component (A) with respect to the total mass of the aqueous dispersion for chemical mechanical polishing are represented by W_{C} (mass %) and W_{A} (mass %), respectively, a ratio W_{C}/W_{A} is preferably 0.01 or more and 1 or less, more preferably 0.03 or more and 0.5 or less, particularly preferably 0.05 or more and 0.3 or less. When the ratio W_{C}/W_{A} falls within the above-mentioned range, the component (A) and the component (C) easily interact with each other, and the polishing rate for the surface to be polished can be further increased in some cases. In addition, it is presumed that the condensate having a high positive charge is easily formed among the components (C), and the dispersibility and dispersion stability of the positively charged silica particles (A) can be further improved by virtue of the condensate in some cases.

### 1.4. (D) Oxidizing Agent

The aqueous dispersion for chemical mechanical polishing according to the first embodiment may include (D) an oxidizing agent (hereinafter sometimes referred to as “component (D)”). When the aqueous dispersion for chemical mechanical polishing according to the first embodiment includes the component (D), the surface to be polished can be oxidized to promote a complexation reaction with a polishing liquid component, to thereby form a brittle modified layer on the surface to be polished, and thus the polishing rate is further increased in some cases.

Examples of the component (D) include ammonium persulfate, potassium persulfate, hydrogen peroxide, ferric nitrate, cerium diammonium nitrate, potassium hypochlorite, ozone, potassium periodate, and peracetic acid. Of those components (D), potassium periodate, potassium hypochlorite, and hydrogen peroxide are preferred, and hydrogen peroxide is more preferred. Those components (D) may be used alone or in combination thereof.

When the aqueous dispersion for chemical mechanical polishing according to the first embodiment includes the component (D), a lower limit value of the content of the component (D) with respect to the total mass of the aqueous dispersion for chemical mechanical polishing is preferably 0.001 mass %, more preferably 0.005 mass %, particularly preferably 0.01 mass %. Meanwhile, an upper limit value of the content of the component (D) with respect to the total mass of the aqueous dispersion for chemical mechanical polishing is preferably 5 mass %, more preferably 3 mass %, particularly preferably 1.5 mass %. When the content of the component (D) falls within the above-mentioned range, the polishing rate of the wiring material, the insulating film material, the barrier metal material, or the like is further increased in some cases. When the component (D) is included at a content falling within the above-mentioned range, an oxide film may be formed on a metal-containing surface to be polished of the wiring material or the like, and hence it is preferred that the component (D) be added immediately before a polishing step of CMP.

### 1.5. Other Components

The aqueous dispersion for chemical mechanical polishing according to the first embodiment may include, as required, a surfactant, a nitrogen-containing heterocyclic compound, a water-soluble polymer, a pH adjusting agent, and the like in addition to water serving as a main liquid medium.

### <Water>

The aqueous dispersion for chemical mechanical polishing according to the first embodiment includes water as a main liquid medium. The water is not particularly limited, but is preferably pure water. The water only needs to be blended as the balance excluding the above-mentioned constituent materials of the aqueous dispersion for chemical mechanical polishing, and the content of the water is not particularly limited.

### <Surfactant>

The aqueous dispersion for chemical mechanical polishing according to the first embodiment may include a surfactant. When the surfactant is included, an appropriate viscosity can be imparted to the aqueous dispersion for chemical mechanical polishing in some cases.

The surfactant is not particularly limited, and examples thereof include an anionic surfactant, a cationic surfactant, and a nonionic surfactant. Examples of the anionic surfactant include: carboxylates, such as a fatty acid soap and an alkyl ether carboxylate; sulfonates, such as an alkylbenzene sulfonate, an alkylnaphthalene sulfonate, and an α-olefin sulfonate; sulfates, such as a higher alcohol sulfate, an alkyl ether sulfate, and a polyoxyethylene alkylphenyl ether sulfate; and fluorine-containing surfactants, such as a perfluoroalkyl compound. Examples of the cationic surfactant include an aliphatic amine salt and an aliphatic ammonium salt. Examples of the nonionic surfactant include: nonionic surfactants each having a triple bond, such as acetylene glycol, an acetylene glycol ethylene oxide adduct, and acetylene alcohol; and polyethylene glycol-type surfactants. Those surfactants may be used alone or in combination thereof.

When the aqueous dispersion for chemical mechanical polishing according to the first embodiment includes the surfactant, the content of the surfactant is preferably from 0.001 mass % to 5 mass %, more preferably from 0.001 mass % to 3 mass %, particularly preferably from 0.01 mass % to 1 mass % with respect to the total mass of the aqueous dispersion for chemical mechanical polishing.

### <Nitrogen-Containing Heterocyclic Compound>

The aqueous dispersion for chemical mechanical polishing according to the first embodiment may include a nitrogen-containing heterocyclic compound. When the nitrogen-containing heterocyclic compound is included, excessive etching of the wiring material can be reduced, and besides, surface roughening after polishing can be prevented in some cases.

The “nitrogen-containing heterocyclic compound” as used herein refers to an organic compound containing at least one kind of heterocycle selected from a five-membered heterocycle and a six-membered heterocycle each having at least one nitrogen atom. Examples of the heterocycle include: five-membered heterocycles, such as a pyrrole structure, an imidazole structure, and a triazole structure; and six-membered heterocycles, such as a pyridine structure, a pyrimidine structure, a pyridazine structure, and a pyrazine structure. Those heterocycles may form a condensed ring. Specific examples thereof include an indole structure, an isoindole structure, a benzimidazole structure, a benzotriazole structure, a quinoline structure, an isoquinoline structure, a quinazoline structure, a cinnoline structure, a phthalazine structure, a quinoxaline structure, and an acridine structure. Of the heterocyclic compounds having such structures, a heterocyclic compound having a pyridine structure, a quinoline structure, a benzimidazole structure, or a benzotriazole structure is preferred.

Specific examples of the nitrogen-containing heterocyclic compound include aziridine, pyridine, pyrimidine, pyrrolidine, piperidine, pyrazine, triazine, pyrrole, imidazole, indole, quinoline, isoquinoline, benzoisoquinolinc, purine, pteridine, triazole, triazolidine, benzotriazole, and carboxybenzotriazole, and derivatives having those skeletons. Of those, benzotriazole, triazole, imidazole, and carboxybenzotriazole are preferred. Those nitrogen-containing heterocyclic compounds may be used alone or in combination thereof.

When the aqueous dispersion for chemical mechanical polishing according to the first embodiment includes the nitrogen-containing heterocyclic compound, the content of the nitrogen-containing heterocyclic compound is preferably from 0.05 mass % to 2 mass %, more preferably from 0.1 mass % to 1 mass %, particularly preferably from 0.2 mass % to 0.6 mass % with respect to the total mass of the aqueous dispersion for chemical mechanical polishing.

### <Water-Soluble Polymer>

The aqueous dispersion for chemical mechanical polishing according to the first embodiment may include a water-soluble polymer. When the water-soluble polymer is included, the water-soluble polymer can adsorb onto the surface to be polished of the wiring material or the like to reduce polishing friction in some cases. The water-soluble polymer is preferably a polycarboxylic acid, more preferably polyacrylic acid, polymaleic acid, and copolymers thereof. Those water-soluble polymers may be used alone or in combination thereof.

The weight-average molecular weight (Mw) of the water-soluble polymer is preferably 1,000 or more and 1,000,000 or less, more preferably 3,000 or more and 800,000 or less. When the weight-average molecular weight of the water-soluble polymer falls within the above-mentioned range, the water-soluble polymer can easily adsorb onto the surface to be polished of the wiring material or the like, and hence the polishing friction can be further reduced in some cases. As a result, the occurrence of polishing flaws on the surface to be polished can be more effectively reduced in some cases. The term “weight-average molecular weight (Mw)” as used herein refers to a weight-average molecular weight in terms of polyethylene glycol measured by gel permeation chromatography (GPC).

When the aqueous dispersion for chemical mechanical polishing according to the first embodiment includes the water-soluble polymer, the content of the water-soluble polymer with respect to the total mass of the aqueous dispersion for chemical mechanical polishing is preferably from 0.01 mass % to 1 mass %, more preferably from 0.03 mass % to 0.5 mass %.

The content of the water-soluble polymer is preferably adjusted so that the viscosity of the aqueous dispersion for chemical mechanical polishing may be less than 10 mPa·s, though the content depends on the weight-average molecular weight (Mw) of the water-soluble polymer. When the viscosity of the aqueous dispersion for chemical mechanical polishing is less than 10 mPa·s, the wiring material or the like can be easily polished at a high rate, and the aqueous dispersion for chemical mechanical polishing can be stably supplied onto an abrasive cloth by virtue of the appropriate viscosity.

### <pH Adjusting Agent>

The aqueous dispersion for chemical mechanical polishing according to the first embodiment may include a pH adjusting agent in order to adjust its pH to 7 or more and 14 or less. Examples of the pH adjusting agent may include bases, such as potassium hydroxide, ethylenediamine, tetramethylammonium hydroxide (TMAH), and ammonia. One or more kinds thereof may be used.

1.6. pH

The aqueous dispersion for chemical mechanical polishing according to the first embodiment has a pH value of 7 or more and 14 or less, preferably 8 or more and 12 or less, more preferably 8.5 or more and 11.5 or less. When the pH value falls within the above-mentioned range, a material to be used for the surface to be polished easily has a negatively charged surface potential. Meanwhile, as described above, the component (A) to be used in the aqueous dispersion for chemical mechanical polishing according to the first embodiment is positively charged through interaction with the component (C). Therefore, when the pH value of the aqueous dispersion for chemical mechanical polishing is adjusted to fall within the above-mentioned range, the surface to be polished and the component (A) are easily brought into contact with each other, and hence the polishing rate is further increased.

Herein, when the pH of the aqueous dispersion for chemical mechanical polishing falls within the above-mentioned range, examples of the material that easily has a negatively charged surface potential include: wiring materials, such as tungsten, copper, cobalt, titanium, and ruthenium; insulating film materials, such as silicon nitride, silicon dioxide, and amorphous silicon; and barrier metal materials, such as titanium nitride and tantalum nitride. When a surface to be polished including two or more kinds of materials selected from those materials is polished, the aqueous dispersion for chemical mechanical polishing according to the first embodiment can efficiently polish the two or more kinds of materials, which results in a further increase in polishing rate for the surface to be polished.

The pH of the aqueous dispersion for chemical mechanical polishing according to the first embodiment may be adjusted by, for example, appropriately increasing or reducing the addition amounts of the component (B), the component (C), and the pH adjusting agent.

In the invention, the pH refers to a hydrogen ion exponent, and its value may be measured under the conditions of 25° C. and 1 atm using a commercially available pH meter (e.g., a tabletop pH meter manufactured by Horiba, Ltd.).

### 1.7. Applications

The aqueous dispersion for chemical mechanical polishing according to the first embodiment has one feature in that the wiring material, the insulating film material, and the barrier metal material present on the surface to be polished are each caused to have a negatively charged surface potential by adjusting the pH of the aqueous dispersion for chemical mechanical polishing to 7 or more and 14 or less, and the positively charged silica particles (A) are used as abrasive grains, to thereby polish the surface to be polished at a high rate. Accordingly, the aqueous dispersion for chemical mechanical polishing according to the first embodiment is suitable as a polishing material to be used for chemical mechanical polishing of a surface to be polished including, out of semiconductor production materials, at least one kind of material selected from the following materials that are particularly easily negatively charged in the above-mentioned pH region: wiring materials, such as tungsten, copper, cobalt, titanium, and ruthenium; insulating film materials, such as silicon nitride, silicon dioxide, and amorphous silicon; and barrier metal materials, such as titanium nitride and tantalum nitride.

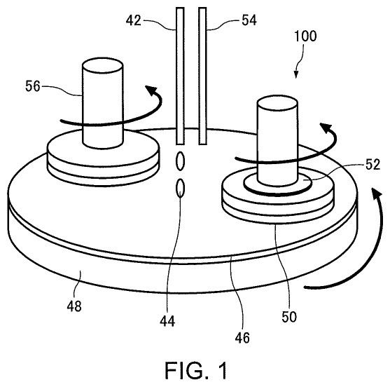

For the above-mentioned chemical mechanical polishing, for example, a polishing apparatus 100 as illustrated in FIG. 1 may be used. FIG. 1 is a perspective view for schematically illustrating the polishing apparatus 100. The above-mentioned chemical mechanical polishing is performed by supplying a slurry (aqueous dispersion for chemical mechanical polishing) 44 from a slurry supply nozzle 42, and while rotating a turntable 48 having attached thereto an abrasive cloth 46, bringing a carrier head 52 holding a substrate 50 into abutment against the abrasive cloth 46. In FIG. 0.1, a water supply nozzle 54 and a dresser 56 are also illustrated.

The polishing load of the carrier head 52 may be selected within the range of from 0.7 psi to 70 psi, and is preferably from 1.5 psi to 35 psi. In addition, the rotation speed of each of the turntable 48 and the carrier head 52 may be appropriately selected within the range of from 10 rpm to 400 rpm, and is preferably from 30 rpm to 150 rpm. The flow rate of the slurry (aqueous dispersion for chemical mechanical polishing) 44 to be supplied from the slurry supply nozzle 42 may be selected within the range of from 10 mL/min to 1,000 mL/min, and is preferably from 50 mL/min to 400 mL/min.

Examples of commercially available products of the polishing apparatus include: a model “EPO-112” or “EPO-222” manufactured by Ebara Corporation; a model “LGP-510” or “LGP-552” manufactured by Lap Master SFT Ltd.; a model “Mirra” or “Reflexion” manufactured by Applied Materials Inc.; a model “POLI-400L” manufactured by G&P Technology; a model “Reflexion LK” manufactured by AMAT; and a model “FLTec-15” manufactured by FILTEC.

### 2. METHOD OF PRODUCING AQUEOUS DISPERSION FOR CHEMICAL MECHANICAL POLISHING

A method of producing an aqueous dispersion for chemical mechanical polishing according to a second embodiment of the invention includes: a first step of adding (A) silica particles, (B) at least one kind selected from the group consisting of organic acids and salts thereof, and (C) at least one kind selected from the group consisting of amino group-containing silane compounds and condensates thereof to water so that, when the content of the component (C) is represented by W_{C} (mass %) and the content of the component (A) is represented by W_{A} (mass %), a ratio W_{C}/W_{A} is 0.01 or more and 1 or less, to thereby obtain an aqueous dispersion; and a second step of further adding (D) an oxidizing agent to the aqueous dispersion after the first step.

In the first step, the aqueous dispersion is prepared by dissolving or dispersing the component (A), the component (B), and the component (C) described above in a liquid medium, such as water. A dissolution method or a dispersion method is not particularly limited, and any method enabling uniform dissolution or dispersion may be applied. In addition, the order of mixing the above-mentioned components and a mixing method for the components are not particularly limited.

In the first step, when the pH of the obtained aqueous dispersion does not fall within a range of from 7 to 14, or when the pH of the obtained aqueous dispersion falls within a range of from 7 to 14 but is required to be further adjusted, it is appropriate to add a pH adjusting agent to adjust the pH of the aqueous dispersion.

In the second step, the aqueous dispersion for chemical mechanical polishing is prepared by further adding the component (D) to the obtained aqueous dispersion. The component (D) is unstable and easily releases oxygen, and easily generates a hydroxy radical having a strong oxidation power. Therefore, it is preferred that the second step be performed immediately before chemical mechanical polishing.

In addition, the aqueous dispersion for chemical mechanical polishing thus obtained may be prepared as an undiluted solution of a concentrated type and used by being diluted with a liquid medium, such as water, at the time of use.

### 3. EXAMPLES

The invention is described below by way of Examples. The invention is not limited to these Examples. The “part” and the “%” used in Examples are by mass unless otherwise indicated.

### 3.1. Example 1

### 3.1.1. Preparation of Aqueous Dispersion for Chemical Mechanical Polishing

0.2 Part by mass of malonic acid, 0.5 part by mass of silica particles A1 having an average particle diameter of 75 nm, and a predetermined amount of potassium hydroxide were loaded into water in a polyethylene bottle having a volume of 1 liter, and 0.05 part by mass of 3-aminopropyltriethoxysilane was added thereto. The contents were sufficiently stirred to give a pH of 9.2. After that, 1.0 part by mass of hydrogen peroxide water was added thereto as an oxidizing agent, and the contents were stirred. Thus, an aqueous dispersion for chemical mechanical polishing to be used in Example 1 was obtained. The average particle diameter of the silica particles was measured with a dynamic light-scattering particle size analyzer “LB-550” manufactured by HORIBA, Ltd.

### 3.1.2. Evaluation Methods

### (1) Evaluation of Polishing Rate

With the use of the aqueous dispersion for chemical mechanical polishing prepared above, test pieces obtained by cutting a tungsten substrate, a silicon dioxide substrate, a titanium nitride substrate, and a tantalum nitride substrate each having no wiring pattern on a resin substrate to 3 cm×3 cm were each used as an object to be polished, and subjected to a chemical mechanical polishing test under the following polishing conditions for 1 minute. Evaluation criteria therefor are as described below. The results are also shown in Table 1.

### <Evaluation Criteria>

A case in which at least one of the conditions of having a polishing rate of tungsten of 50 Å/min or more, having a polishing rate of silicon dioxide of 150 Å/min or more, and having a polishing rate of titanium nitride of 500 Å/min or more is not satisfied is represented by Symbol “C”.

A case in which all of the conditions of having a polishing rate of tungsten of 50 Å/min or more, having a polishing rate of silicon dioxide of 150 Å/min or more, and having a polishing rate of titanium nitride of 500 Å/min or more are satisfied is represented by Symbol “B”.

A case in which all of the conditions of having a polishing rate of tungsten of 100 Å/min or more, having a polishing rate of silicon dioxide of 150 Å/min or more, and having a polishing rate of titanium nitride of 1,000 Å/min or more are satisfied is represented by Symbol “A”.

A case in which all of the conditions of having a polishing rate of tungsten of 100 Å/min or more, having a polishing rate of silicon dioxide of 150 Å/min or more, and having a polishing rate of titanium nitride of 1,500 Å/min or more are satisfied is represented by Symbol “AA”.

A case of having the rating of “AA” also satisfies the conditions of “A” and “B”, but the rating of “AA” is prioritized thereover. Similarly, a case of having the rating of “A” also satisfies the conditions of “B”, but the rating of “A” is prioritized thereover.

### <Polishing Conditions>

Polishing apparatus: model “FLTec-15” manufactured by FILTEC

Polishing pad: “H600” manufactured by Fujibo

Supply rate of aqueous dispersion for chemical mechanical polishing: 100 mL/min

Surface plate rotation speed: 100 rpm

Head rotation speed: 90 rpm

Head pressure: 3.8 psi

Silicon dioxide film thickness evaluation apparatus: model “F20-HS” manufactured by Filmetrics Japan, Inc.

Resistivity evaluation apparatus for tungsten, titanium nitride, and tantalum nitride: MODEL Σ-5 manufactured by NPS Co., Ltd.

Polishing rate (Å/min) of each of tungsten, titanium nitride, and tantalum nitride=(((volume resistivity specific to each substrate/resistance value of each substrate before polishing)−(volume resistivity specific to each substrate/resistance value of each substrate after polishing))/polishing time (sec))×60

Polishing rate (Å/min) of silicon dioxide=((thickness of silicon dioxide substrate before polishing−thickness of silicon dioxide substrate after polishing)/polishing time (sec))×60

### (2) Evaluation of Polishing Flaw

The surface of the tungsten substrate subjected to the chemical mechanical polishing test in the “Evaluation of Polishing Rate” section was observed with a laser microscope (model “OLS4000”, manufactured by Olympus Corporation). Evaluation criteria therefor are as described below. The evaluation results are shown in Table 1.

### <Evaluation Criteria>

In Table 1,

a case in which there is no flaw is represented by Symbol “A”;
a case in which flaws are partly present is represented by Symbol “B”; and
a case in which flaws are present on the entire surface is represented by Symbol “C”.

### (3) Evaluation of Dispersibility

20 mL of the aqueous dispersion for chemical mechanical polishing obtained above was collected in a polystyrene bottle, and was left to stand still for 5 hours. After 5 hours, a value obtained by dividing the height of a supernatant liquid by the height of the entire liquid (this value was referred to as “supernatant ratio”) was used as an indicator of dispersibility. Evaluation criteria therefor are as described below. The evaluation results are shown in Table 1.

### <Evaluation Criteria>

In Table 1,

a case in which the supernatant ratio is 0.00 or more and less than 0.30 is represented by Symbol “A” because of having satisfactory dispersibility;
a case in which the supernatant ratio is 0.30 or more and less than 0.80 is represented by Symbol “B” because there is no problem in use in terms of dispersibility; and
a case in which the supernatant ratio is 0.80 or more is represented by Symbol “C” because of having poor dispersibility.

### 3.2. Examples 2 to 8 and Comparative Examples 1 to 4

An aqueous dispersion for chemical mechanical polishing was prepared in the same manner as in Example 1 except that the kinds and contents of the components were changed as shown in Table 1 or Table 2 below. The evaluation tests were performed in the same manner as in Example 1.

### 3.3. Evaluation Results

The compositions and evaluation results of the aqueous dispersions for chemical mechanical polishing of Examples and Comparative Examples are shown in Table 1 and Table 2 below.

TABLE 1

| | | | Example 1 | Example 2 | Example 3 | Example 4 |
|---|---|---|---|---|---|---|
| Aqueous | (A) Abrasive grains | Kind | Silica | Silica | Silica | Silica |
| dispersion for | | | particles A1 | particles A2 | particles A1 | particles A1 |
| chemical | | Average particle diameter | 75 | 40 | 75 | 75 |
| mechanical | | (nm) | | | | |
| polishing | | Content (part by mass) | 0.5 | 0.5 | 0.5 | 0.5 |
| | (B) Organic acid | Kind | Malonic acid | Malonic acid | Maleic acid | Malonic acid |
| | | Content (part by mass) | 0.2 | 0.2 | 0.2 | 0.2 |
| | (C) Amino | Kind | 3-Aminopropyl- | 3-Aminopropyl- | 3-Aminopropyl- | N-(2-amino |
| | group-containing | | triethoxysilane | triethoxysilane | triethoxysilane | ethyl)-3- |
| | silane compound | | | | | aminopropyl- |
| | | | | | | trimethoxysilane |
| | | Content (part by mass) | 0.05 | 0.05 | 0.05 | 0.05 |
| | (D) Oxidizing agent | Kind | Hydrogen | Hydrogen | Hydrogen | Hydrogen |
| | | | peroxide | peroxide | peroxide | peroxide |
| | | Content (part by mass) | 1 | 1 | 1 | 1 |
| | Other additives | pH adjusting agent | Potassium | Potassium | Potassium | Potassium |
| | | | hydroxide | hydroxide | hydroxide | hydroxide |
| | Liquid medium | Water | Balance | Balance | Balance | Balance |
| | W_{C}/W_{A} | | 0.1 | 0.1 | 0.1 | 0.1 |
| | pH | | 9.2 | 9.2 | 9.2 | 9.2 |
| Evaluation | Polishing rate | Tungsten substrate (Å/min.) | 377 | 407 | 334 | 95 |
| item | | Silicon dioxide substrate | 302 | 234 | 223 | 399 |
| | | (Å/min.) | | | | |
| | | Titanium nitride substrate | 1,719 | 1,491 | 1,735 | 1,049 |
| | | (Å/min.) | | | | |
| | | Tantalum nitride substrate | 1,450 | 1,300 | 1,323 | 629 |
| | | (Å/min.) | | | | |
| | | Evaluation of polishing rate | AA | A | AA | B |
| | Polishing flaw | | A | A | A | A |
| | Dispersibility | Supernatant ratio | 0.13 | 0.31 | 0.03 | 0.68 |
| | | Evaluation | A | B | A | B |
| | | | Example 5 | Example 6 | Example 7 | Example 8 |
| Aqueous | (A) Abrasive grains | Kind | Silica | Silica | Silica | Silica |
| dispersion for | | | particles A1 | particles A1 | particles A1 | particles A1 |
| chemical | | Average particle diameter | 75 | 75 | 75 | 75 |
| mechanical | | (nm) | | | | |
| polishing | | Content (part by mass) | 0.5 | 0.5 | 0.5 | 0.5 |
| | (B) Organic acid | Kind | Malonic acid | Malonic acid | Malonic acid | Malonic acid |
| | | Content (part by mass) | 0.2 | 0.2 | 0.2 | 0.2 |
| | (C) Amino | Kind | 3-Aminopropyl- | 3-Aminopropyl- | 3-Aminopropyl- | 3-Aminopropyl- |
| | group-containing | | triethoxysilane | triethoxysilane | triethoxysilane | triethoxysilane |
| | silane compound | | | | | |
| | | Content (part by mass) | 0.1 | 0.5 | 0.05 | 0.05 |
| | (D) Oxidizing agent | Kind | Hydrogen | Hydrogen | Hydrogen | Hydrogen |
| | | | peroxide | peroxide | peroxide | peroxide |
| | | Content (part by mass) | 1 | 1 | 1 | 1 |
| | Other additives | pH adjusting agent | Potassium | Potassium | Potassium | Potassium |
| | | | hydroxide | hydroxide | hydroxide | hydroxide |
| | Liquid medium | Water | Balance | Balance | Balance | Balance |
| | W_{C}/W_{A} | | 0.2 | 1 | 0.1 | 0.1 |
| | pH | | 9.2 | 9.2 | 8.3 | 11.0 |
| Evaluation | Polishing rate | Tungsten substrate (Å/min.) | 235 | 66 | 316 | 355 |
| item | | Silicon dioxide substrate | 267 | 192 | 342 | 152 |
| | | (Å/min.) | | | | |
| | | Titanium nitride substrate | 1,359 | 584 | 1,464 | 1,768 |
| | | (Å/min.) | | | | |
| | | Tantalum nitride substrate | 1,249 | 502 | 1,416 | 1,194 |
| | | (Å/min.) | | | | |
| | | Evaluation of polishing rate | A | B | A | AA |
| | Polishing flaw | | A | B | A | A |
| | Dispersibility | Supernatant ratio | 0.11 | 0.09 | 0.14 | 0.29 |
| | | Evaluation | A | A | A | A |

TABLE 2

| | | | Comparative | Comparative | Comparative | Comparative |
|---|---|---|---|---|---|---|
| | | | Example 1 | Example 2 | Example 3 | Example 4 |
| Aqueous | (A) Abrasive | Kind | Silica particles A1 | Silica particles A1 | Alumina particles | Alumina particles |
| dispersion | grains | Average particle diameter (nm) | 75 | 75 | 240 | 240 |
| for chemical | | Content (part by mass) | 0.5 | 0.5 | 0.5 | 0.5 |
| mechanical | (B) Organic acid | Kind | Malonic acid | Malonic acid | Maleic acid | Malonic acid |
| polishing | | Content (part by mass) | 0.2 | 0.2 | 0.2 | 0.2 |
| | (C) Amino | Kind | — | 3-Aminopropyl- | 3-Aminopropyl- | 3-Aminopropyl- |
| | group-containing | | | triethoxysilane | triethoxysilane | triethoxysilane |
| | silane compound | Content (part by mass) | — | 0.05 | 0.05 | 0.1 |
| | (D) Oxidizing | Kind | Hydrogen | Hydrogen | Hydrogen | Hydrogen |
| | agent | | peroxide | peroxide | peroxide | peroxide |
| | | Content (part by mass) | 1 | 1 | 1 | 1 |
| | Other additives | pH adjusting agent | Potassium | Potassium | Potassium | Potassium |
| | | | hydroxide | hydroxide | hydroxide | hydroxide |
| | Liquid medium | Water | Balance | Balance | Balance | Balance |

| | | | | |
|---|---|---|---|---|
| W_{C}/W_{A} | — | 0.1 | 0.1 | 0.2 |
| pH | 9.2 | 2.0 | 9.2 | 9.2 |

| | | | | | | |
|---|---|---|---|---|---|---|
| Evaluation | Polishing rate | Tungsten substrate (Å/min.) | 93 | 75 | 417 | 222 |
| item | | Silicon dioxide substrate (Å/min.) | 48 | 85 | 69 | 64 |
| | | Titanium nitride substrate | 471 | 230 | 1,247 | 1,110 |
| | | (Å/min.) | | | | |
| | | Tantalum nitride substrate | 150 | 130 | 444 | 405 |
| | | (Å/min.) | | | | |
| | | Evaluation of polishing rate | C | C | C | C |

| Polishing flaw | | A | A | C | C |
|---|---|---|---|---|---|
| Dispersibility | Supernatant ratio | 0 | 0.13 | 0.82 | 0.91 |
| | Evaluation | A | A | C | C |

The following products and reagents were used as the components shown in Table 1 and Table 2.

### <Abrasive Grains>

Silica particles A1: colloidal silica manufactured by Fuso Chemical Co., Ltd., average particle diameter: 75 nm

Silica particles A2: colloidal silica manufactured by Fuso Chemical Co., Ltd., average particle diameter: 40 nm

Alumina particles: manufactured by Saint-Gobain Ceramic Materials, Inc., product number “7992 Alumina”

### <Organic Acid>

Malonic acid: manufactured by Fuso Chemical Co., Ltd., product name “Malonic acid”

Maleic acid: manufactured by Juzen Chemical Corporation, product name “Maleic acid”

### <Amino Group-containing Silane Compound>

3-Aminopropyltriethoxysilane: manufactured by Tokyo Chemical Industry Co., Ltd., product name “3-Aminopropyltriethoxysilane”

N-(2-Aminoethyl)-3-aminopropyltrimethoxysilane: manufactured by Tokyo Chemical Industry Co., Ltd., product name “3-(2-Aminoethylamino)propyltrimethoxysilane”

### <Oxidizing Agent>

Hydrogen peroxide: manufactured by Fujifilm Wako Pure Chemical Corporation, product name “Hydrogen peroxide water (30%)”

### <Other Additive>

Potassium hydroxide: pH adjusting agent manufactured by Kanto Chemical Co., Inc.

It was found that, according to each of the aqueous dispersions for chemical mechanical polishing of Examples 1 to 8, the tungsten substrate, the silicon dioxide substrate, the titanium nitride substrate, and the tantalum nitride substrate were able to be polished at high rates, and the occurrence of polishing flaws on the surface to be polished was able to be reduced by virtue of the silica particles (A) having satisfactory dispersibility.

The aqueous dispersion for chemical mechanical polishing of Comparative Example 1 did not include the amino group-containing silane compound (C). Therefore, the silica particles (A) were not positively charged and were negatively charged, and hence were in a state of being hardly brought into contact with surfaces of the various substrates negatively charged, with the result that the substrates were not able to be polished at high rates.

The aqueous dispersion for chemical mechanical polishing of Comparative Example 2 had a pH of 2.0. Therefore, surfaces of the various substrates were not negatively charged, and hence were in a state of being hardly brought into contact with the positively charged silica particles (A), with the result that the substrates were not able to be polished at high rates.

In each of the aqueous dispersions for chemical mechanical polishing of Comparative Example 3 and Comparative Example 4, the amino group-containing silane compound (C) did not interact with alumina, and hence a repulsive force was not generated, which resulted in poor dispersibility. In particular, the silicon dioxide substrate was not able to be polished at a high rate, and a large number of polishing flaws were generated on the surface to be polished owing to the alumina.

From the above-mentioned results, it was found that the aqueous dispersion for chemical mechanical polishing according to the invention enabled polishing of the wiring material, the insulating film material, and the barrier metal film material at high rates, and was able to reduce the occurrence of the polishing flaws on the surface to be polished.

The invention is not limited to the embodiments described above, and various modifications may be made thereto. For example, the invention includes configurations that are substantially the same (for example, in function, method, and results, or in objective and effects) as the configurations described in the embodiments. The invention also includes configurations in which non-essential elements described in the embodiments are replaced by other elements. The invention also includes configurations having the same effects as those of the configurations described in the embodiments, or configurations capable of achieving the same objectives as those of the configurations described in the embodiments. The invention further includes configurations obtained by adding known art to the configurations described in the embodiments.

Although some embodiments of the invention have been described in detail above, those skilled in the art would readily appreciate that many modifications are possible in the embodiments without materially departing from the novel teachings and advantages of the invention. Accordingly, all such modifications are assumed to be included within the scope of the invention.

What is claimed is:

1. An aqueous dispersion for chemical mechanical polishing, comprising:
(A) silica particles;
(B) at least one kind selected from the group consisting of organic acids and salts thereof; and
(C) at least one kind selected from the group consisting of amino group-containing silane compounds and condensates thereof, and
having a pH of 7 or more and 14 or less.

2. The aqueous dispersion for chemical mechanical polishing according to claim 1, wherein, when a content of the component (C) is represented by W_{C} (mass %) and a content of the component (A) is represented by W_{A} (mass %), a ratio W_{C}/W_{A} is 0.01 or more and 1 or less.

3. The aqueous dispersion for chemical mechanical polishing according to claim 1, wherein, when a content of the component (C) is represented by W_{C} (mass %) and a content of the component (A) is represented by W_{A} (mass %), a ratio W_{C}/W_{A} is 0.03 or more and 0.5 or less.

4. The aqueous dispersion for chemical mechanical polishing according to claim 1, wherein the component (C) comprises an aminoalkoxysilane.

5. The aqueous dispersion for chemical mechanical polishing according to claim 1, wherein the component (C) comprises an aminopropyltrialkoxysilane.

6. The aqueous dispersion for chemical mechanical polishing according to claim 1, wherein a content of the component (A) with respect to a total mass of the aqueous dispersion for chemical mechanical polishing is 0.05 mass % or more and 10 mass % or less.

7. The aqueous dispersion for chemical mechanical polishing according to claim 1, wherein a content of the component (B) with respect to a total mass of the aqueous dispersion for chemical mechanical polishing is 0.001 mass % or more and 2 mass % or less.

8. The aqueous dispersion for chemical mechanical polishing according to claim 1, wherein a content of the component (C) with respect to a total mass of the aqueous dispersion for chemical mechanical polishing is 0.005 mass % or more and 10 mass % or less.

9. The aqueous dispersion for chemical mechanical polishing according to claim 1, further comprising (D) an oxidizing agent.

10. The aqueous dispersion for chemical mechanical polishing according to claim 9, wherein a content of the component (D) with respect to a total mass of the aqueous dispersion for chemical mechanical polishing is 0.001 mass % or more and 5 mass % or less.

11. The aqueous dispersion for chemical mechanical polishing according to claim 1, wherein the aqueous dispersion for chemical mechanical polishing is used for polishing of a substrate comprising two or more kinds selected from the group consisting of silicon nitride, silicon dioxide, amorphous silicon, tungsten, copper, cobalt, titanium, ruthenium, titanium nitride, and tantalum nitride.

12. A method of producing an aqueous dispersion for chemical mechanical polishing, comprising:
a first step of adding (A) silica particles, (B) at least one kind selected from the group consisting of organic acids and salts thereof, and (C) at least one kind selected from the group consisting of amino group-containing silane compounds and condensates thereof to water so that, when a content of the component (C) is represented by W_{C} (mass %) and a content of the component (A) is represented by W_{A} (mass %), a ratio W_{C}/W_{A} is 0.01 or more and 1 or less, to thereby obtain an aqueous dispersion; and
a second step of further adding (D) an oxidizing agent to the aqueous dispersion after the first step.
